(19) United States
(12) Patent Application Publication
(10) Pub. No.: US 2010/0072827 A1
(43) Pub. Date: Mar. 25, 2010

(54) Mobile power source for use with a hand-held machine and method of operating

(76) Inventor: Brian R. Norstrom, Kahului, HI (US)

Correspondence Address: Brian R. Norstrom, 762 Honowai St., Kahului, Maui, HI, 96732, US

(21) Appl. No.: 12/284,674

(22) Filed: Sep. 22, 2008

(51) Int. Cl. H02B 1/24; G01R 1/20

(52) U.S. Cl. 307/112; 307/154

(57) ABSTRACT

A mobile power source for use with a hand-held machine and a method of operating the power source are described. The mobile power source comprises a power supply having an attachment device configured to couple the power supply to an operator, whereby the coupling of the power supply to the operator permits substantially free movement of the hand-held machine by the operator while providing power to the hand-held machine. Furthermore, a power controller is coupled to the power supply and configured to control the output of power from the power supply to the hand-held machine, whereby the power controller is remotely coupled to the power supply via a wireless connection.

### BACKGROUND OF THE INVENTION

1. Field of the Invention

The present invention relates to a power source for use with a hand-held machine and a method of operating and, in particular, a mobile power source that permits substantially free movement of the hand-held machine by an operator while providing power to the hand-held machine.

2. Description of Related Art

For many years, skin markings, often times referred to as tattoos, have been applied for adornment, symbolic, patriotic, ethnic, or religious identification and artistic expression. Additional interests for such skin alterations include cosmetic, corrective or camouflage tattooing as a technique for providing, for example, permanent make-up or color restoration for various body parts including scars and skin conditions occurring from losses suffered by aging, birth defects, cancer treatment or skin changes.

Consequently, hand-held instruments configured to produce an enhanced coloration of the skin have also evolved through the years. These instruments include motor driven intradermal injection devices that inject ink, dye, or other materials (referred to hereafter collectively as “ink”) just below the skin, such that the ink is retained within the skin and the pattern of color of the ink remains visible. Conventionally, motor driven devices comprise a skin-penetrating needle which has the capacity to store some quantity of ink, a mechanism to reciprocate the needle for repeated punctures of the skin to implant the ink under the skin in the desired pattern, and a housing for the device which the operator holds and often uses to guide the device. Additionally, with some devices the operator repeatedly dips the needle in a pool of ink to coat the needle, while in other devices a reservoir provides a continuous supply of ink to the needle.

Furthermore, the motorized injection device includes a power source and an on/off switch that is utilized to intermittently provide power to the reciprocating drive mechanism. Common to most power systems, an electrical cord couples the hand-held, motorized device to an electrical outlet via a power supply resting on the floor, while the on/off switch comprises a foot pedal coupled to the power supply via another electrical cord. The use of these electrical cords confines the operator of complete freedom when operating the hand-held device. This restraint of movement typically increases the time required for performing an injection procedure and can lead to some inaccuracy during injection of ink by a less skilled operator.

### SUMMARY OF THE INVENTION

According to one embodiment, a mobile power source and method of operating the power source is described for providing power to a hand-held device.

According to another embodiment, a mobile power source for use with a hand-held machine is described, comprising: a power supply configured to provide power to a hand-held machine, wherein the power supply excludes an electrical cord that tethers the power supply to an electrical outlet; an attachment device coupled to the power supply and configured to fasten the power supply to an operator of the hand-held machine; and a power cable configured to couple an output of the power supply to the hand-held machine. Furthermore, a power controller can be coupled to the power supply and configured to control the output of power from the power supply to the hand-held machine, whereby the power controller is remotely coupled to the power supply via a wireless connection.

According to another embodiment, a tattooing system is described, comprising: a hand-held tattoo machine; a mobile power supply configured to provide power to the hand-held tattoo machine; an attachment device configured to fasten the mobile power supply to an operator of the hand-held tattoo machine; a power cable configured to couple an output of said power supply to the hand-held machine; and a foot pedal coupled to the power supply via a wireless connection and configured to turn on and turn off the output of power from the mobile power supply to the hand-held tattoo machine, wherein the mobile power supply excludes an electrical cord that tethers the mobile power supply to an electrical outlet.

According to yet another embodiment, a method of providing power to a tattoo machine utilized by an operator is described, comprising: attaching a power supply configured to provide power to the tattoo machine to the operator; coupling an electrical power cord from an output of the tattoo machine to an input to the tattoo machine; disposing a foot pedal configured to control the output of power from the power supply on the floor in proximity to the power supply such that the foot pedal communicates with the power supply via a wireless connection; operating the tattoo machine; and controlling the output of power from the power supply to the tattoo machine by operating the foot pedal.

### BRIEF DESCRIPTION OF THE DRAWINGS

In the accompanying drawings:

FIG. 1 presents a system view of a power source operable with a hand-held machine according to an embodiment;

FIG. 2 provides a schematic diagram of a power source according to another embodiment;

FIG. 3 illustrates an exemplary power source according to another embodiment;

FIG. 4 provides an illustration of an attachment device for coupling a power source to an operator according to an embodiment;

FIG. 5 provides an illustration of an attachment device for coupling a power source to an operator according to another embodiment;

FIG. 6 provides an illustration of an attachment device for coupling a power source to an operator according to yet another embodiment; and

FIG. 7 illustrates a method of operating a power source according to another embodiment.

### DETAILED DESCRIPTION OF EXEMPLARY EMBODIMENTS

In the following description, in order to facilitate a thorough understanding of the invention and for purpose of explanation and not limitation, specific details are set forth, such as a particular geometry of the mobile power source and descriptions of various components. However, it should be understood that the invention may be practiced in other embodiments that depart from these specific details.

As described above, conventional hand-held machines, such as hand-held tattoo machines, receive power through an electrical cord coupling the hand-held machine to an (alternating current, AC) electrical outlet via a power supply resting on the floor. Moreover, as in the case of a tattoo machine, a second electrical cord is employed to couple an on/off switch comprising a foot pedal to the power supply. The use of these electrical cords restricts the operator of complete freedom when operating the hand-held machine. Therefore, the inventor has recognized a need for providing additional freedom to the operator of the hand-held machine.

Furthermore, the inventor recognizes the benefit for the operator to utilize the mobile power source with a variety of hand-held machines. For example, in the case of tattoo machines, the operator may desire to operate any conventional tattoo machine, including legacy equipment, with the mobile power source.

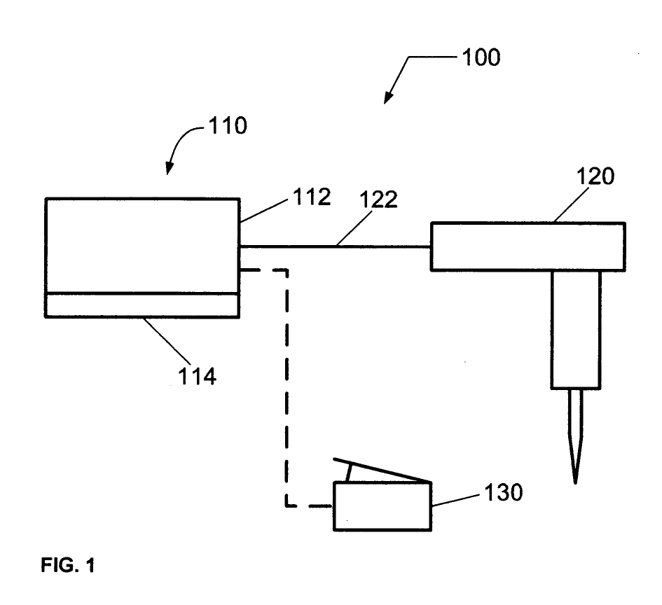

Referring now to the drawings, wherein like reference numerals designate identical or corresponding parts throughout the several views, FIG. 1 illustrates a power system 100 for use with a hand-held machine 120. The power system 100 comprises a mobile power source 110 configured to provide power to the hand-held machine 120. As shown in FIG. 1, the mobile power source 110 comprises a power supply 112 configured to couple power to the hand-held machine 120 via a power cable 122 extending from an output of the power supply 112 to an input to the hand-held machine 120.

Furthermore, the mobile power source 110 comprises an attachment device 114 coupled to the power supply 112, and configured to couple the power supply 112 to the operator. The coupling of the power supply 112 to the operator via the attachment device 114 can permit substantially free movement of the hand-held machine 120 by the operator while providing power to the hand-held machine 120.

The hand-held machine 120 may comprise a tattoo machine configured to inject ink beneath the skin in order to produce a skin marking or tattoo. The tattoo machine can include any industry standard tattoo machine.

Although the discussion which follows addresses the use of a mobile power source with a tattoo machine, it should be understood that the mobile power source may be operated with a variety of hand-held machines. For example, other hand-held machines may include power tools, home appliances, medical equipment, etc.

The power supply 112 comprises a stored energy source configured to be mountable on the operator using the attachment device 114 and configured to provide electrical power to the hand-held machine 120 sufficient to operate the hand-held machine 120. For example, the stored energy source can include one or more batteries, or one or more rechargeable batteries, or a combination thereof. Additionally, for example, the power supply 112 can comprise one or more rechargeable lithium-ion batteries or lithium-polymer batteries.

Referring still to FIG. 1, the power system 100 can further comprise a power controller 130. The power controller 130 is coupled to the mobile power source 110 and configured to control the output of power from the power supply 112 to the hand-held machine 120. For example, the power controller can comprise an operator-activated switch configured to turn on and turn off the output of power from the power supply 112 to the hand-held machine 120. As illustrated in FIG. 1, the power controller 130 may comprise a foot pedal. For example, when the foot pedal is depressed by the operator, power is coupled from the power supply 112 to the hand-held machine 120 and, when the pedal is released, power is decoupled from the power supply 112 to the hand-held machine 120. The power controller 130 may include one or more batteries, or one or more rechargeable batteries, or a combination thereof. Additionally, for example, the power controller 130 may comprise one or more lithium batteries, or one or more rechargeable lithium-ion batteries or lithium-polymer batteries.

The power controller 130 may be coupled to the power supply 112 via an electrical cord. Alternatively, the power controller 130 may be coupled to the power supply 112 via a wireless connection (as indicated by the dashed line in FIG. 1). The power controller 130 can comprise a radio frequency (RF) transmitter configured to transmit a RF signal and the power supply 112 comprises a RF receiver configured to receive the RF signal transmitted from the RF transmitter, wherein the RF signal is configured to designate a level of power to be output from the power supply 112. For example, the wireless connection can comprise a short range wireless RF control link having a 64 bit unique security code that prevents the system from being unintentionally commanded by noise or other wireless remote units operating nearby. Additionally, for example, the foot pedal can comprise a single unit consisting of a pressure sensor, a coded radio frequency transmitter, a built in antenna and a battery.

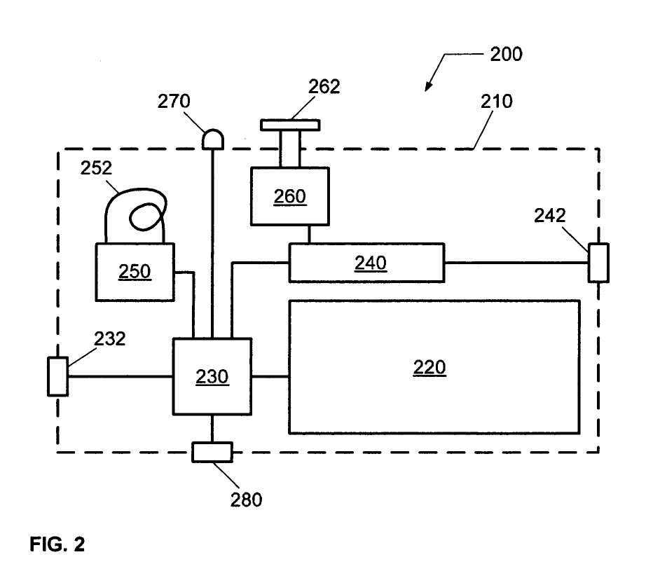

Referring now to FIG. 2, a schematic illustration of a power supply 200 is provided according to another embodiment. The power supply 200 comprises an enclosure 210 configured to house the components of the power supply 200 and configured to couple the power supply 200 to the attachment device utilized to fasten the power supply to the operator. The power supply 200 may be configured to be fixedly coupled to the attachment device, or the power supply 200 may be configured to be removably coupled to the attachment device. The power supply 200 comprises a stored energy source 220, and a power supply control circuit 230 coupled to the stored energy source 220 and configured to generate control voltages sufficient for operating the power supply 200. The stored energy source 220 can include a battery pack having one or more batteries, or one or more rechargeable batteries, or a combination thereof.

The power supply 200 further comprises a RF receiver 250 having RF antenna 252 that is configured to receive a RF signal from a remotely located power controller, such as a foot pedal. The RF receiver provides an input signal to the power supply control circuit 230 that is related to the received RF signal, and the power supply control circuit 230 is configured to decode the input signal and adjust the level of power output from the stored energy source 220 accordingly. For example, the input signal to the power supply control circuit 230 can activate or deactivate the output of power from the stored energy source 220 to the hand-held machine.

The power supply 200 can further comprise a voltage regulator circuit 240 configured to serve as a voltage boost regulator and power conditioner. The voltage regulator circuit 240 is configured to adjust the output voltage of the power supply 200 provided input from the operator. For example, the power supply 200 can comprise a user-operated potentiometer 260 having a control dial 262 that can be used to set the output voltage for the power supply. Power from stored energy source 220 is coupled to a power cable extending from an output jack 242 in power supply 200 to the hand-held machine.

Additionally, the power supply 200 can comprise an input jack 232 for coupling a battery charger to the power supply 200 in order to restore the stored energy source 220 to its fully charged level or a partially charged level.

Further yet, the power supply 200 can comprise an on/off switch 280 configured to turn on or turn off the power supply 200.

Optionally, the power supply 200 comprises light source 270, such as a light-emitting diode (LED), configured to light when the stored energy source 220 reaches a relatively low level. For example, when the energy level of the stored energy source 220 becomes less than or equal to approximately 20% of the fully charged level, the LED 270 emits light. Alternatively, for example, when the energy level of the stored energy source 220 becomes less than or equal to approximately 10% of the fully charged level, the LED 270 emits light.

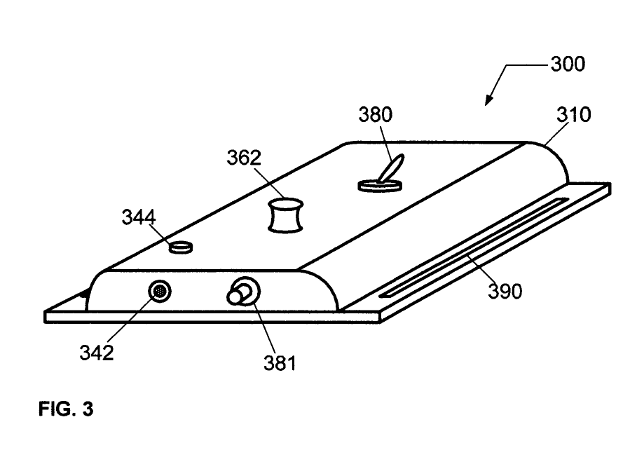

Referring now to FIG. 3, a perspective view of a power supply 300 is provided according to another embodiment. The power supply 300 comprises an enclosure 310 configured to house the components of the power supply 300. For example, the internal components can include many of the components described above including a stored energy source, a RF receiver and a voltage regulator.

Furthermore, the power supply 300 comprises an output jack 340 configured to couple power through a power cable to the hand-held machine. The power cable comprises a first end configured to mate with the output jack 340 and a second end configured to mate with the hand-held machine. The first end can, for example, comprise an industry standard plug such as a RCA plug or mono plug. Additionally, for example, the second end can comprise a pair of leads configured to couple to the terminals of the hand-held machine, such as the terminals of a tattoo machine. Furthermore, the power supply 300 may include a plug release 342 configured to release the power cable for easy detachment.

As illustrated in FIG. 3, the power supply further comprises a control dial 362 whereby the operator can adjust the output voltage of the power supply 300. Additionally, the power supply 300 can provide an on/off switch 380 for turning the power supply on and off, and it may further include a power light 381 to indicate the power supply 300 is turned on, for example.

In FIG. 3, one embodiment for packaging power supply 300 is illustrated. However, other embodiments are envisioned. For example, various control features (e.g., knobs, output jack, etc.) may be located on the front face of the enclosure rather than on both the front surface and the top surface of the enclosure.

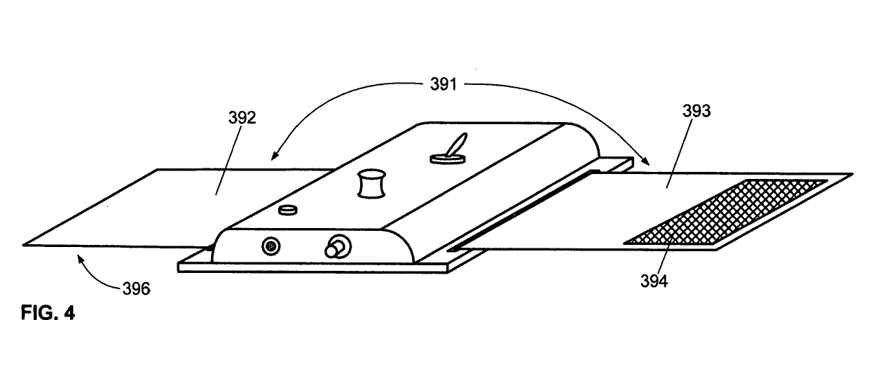

Furthermore, as shown in FIGS. 3 and 4, the enclosure 310 is configured to couple the power supply 300 to an attachment device 391 utilized to fasten the power supply to the operator. For example, the attachment device 391 can comprise a strap configured to couple the power supply 300 to a body part of the operator, such as an arm. The strap can include an elastic strap or it can include an inelastic strap. Additionally, the strap can include distal ends configured to latch with one another, or the strap may include a continuous band.

For example, as shown in FIG. 4, the strap can comprise a first end 392 and a second end 393 that are configured to slide through slots 390 on either side of the enclosure 310, wrap around the operator's arm, and couple to one another via a fastener in order to secure the power supply to the operator's arm. The fastener can comprise Velcro® patches 394 and 396 that are configured to mate with one another.

Alternatively, the fastener can include a clasp, latch, button, snap, zipper, laces, buckle, double bar buckle, side release buckle, or any fastening device for coupling two strap ends or tightening a sleeve. Alternatively yet, the strap may comprise two ends which are tied to one another.

Furthermore, the attachment device may include a strap configured to fasten the power supply to any body part of the operator including, for example, an arm or forearm, a leg, a waist, etc. Alternatively, the attachment device may include a clip configured to fasten the power supply to a belt on the operator.

The power supply may be configured to be fixedly coupled to the attachment device, or the power supply may be configured to be removably coupled to the attachment device. For example, as shown in FIG. 4, power supply 300 is removably coupled to the attachment device.

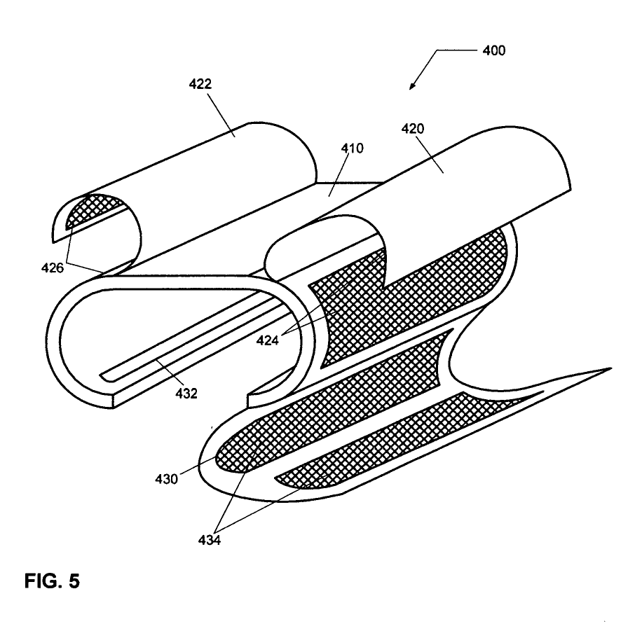

Referring now to FIG. 5, an attachment device 400 is illustrated according to another embodiment. The attachment device 400 comprises an attachment member 410 configured to extend around or partially around the arm or forearm of an operator. For example, the attachment member 410 may be fabricated from a non-flexible, semi-flexible, or flexible material. The attachment member 410 is fastened or secured to the arm of the operator by extending arm strap 430 through slot 432 on attachment member 410 and folding the strap 430 back upon itself such that Velcro® patches 434 mate with one another. Strap 430 may be adjusted by the operator to tighten or loosen the attachment member 410.

Furthermore, the attachment member 410 is configured to receive a mobile power source, such as the power source depicted in FIG. 3. Power supply straps 420 and 422 can extend through slots 390 and fold back upon themselves such that Velcro® patches 424 and 426 mate.

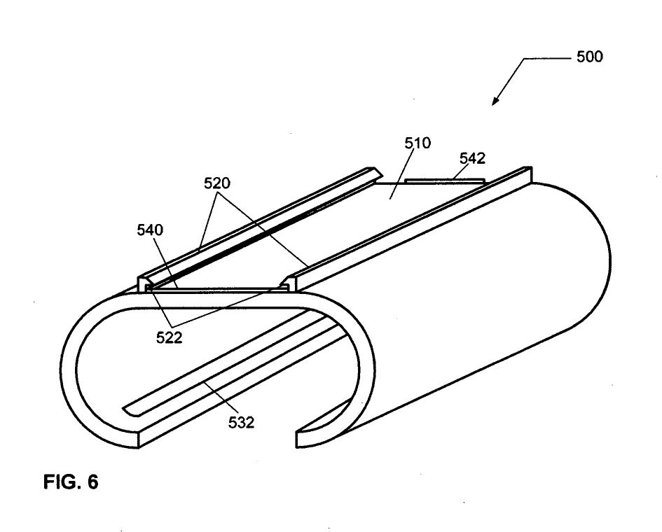

Referring now to FIG. 6, an attachment device 500 is illustrated according to yet another embodiment. The attachment device 500 comprises an attachment member 510 configured to extend around or partially around the arm or forearm of an operator. For example, the attachment member 510 may be fabricated from a non-flexible, semi-flexible, or flexible material. The attachment member 510 comprises a clasping or latching mechanism that permits attaching or detaching the power supply. For example, the power supply can “snap-on” or “snap-off” the attachment member 510.

As shown in FIG. 6, the power supply, such as the power supply shown in FIG. 3, can be slidably coupled to the attachment 510. The attachment member 510 can comprise a pair of rails 520 having rail lips 522 configured to retain an edge of the power supply. Furthermore, the attachment member 510 comprises a stop end 540 configured to prevent further movement of the power supply and optionally a latch end 542 configured to latch the power supply, whereby the stop end 540 and the optional latch end 542 operate in tandem to secure the power supply once it is inserted into the attachment member 510. Once the power supply is latched, it can be released by the operator when, for example, the latch end is depressed.

The attachment member 510 may, for example, be fastened or secured to the arm of the operator by extending an arm strap (not shown) through slot 532 on attachment member 510 and folding the strap back upon itself such that Velcro® patches (not shown) mate with one another. Other methods for securing the power source to the operator are contemplated above.

In FIGS. 3 through 6, although several embodiments are illustrated for attaching a power supply to any body part of the operator, other embodiments are contemplated. For example, the power supply may insert (e.g., slip or slide) into a sleeve or case which, in turn, may be attached to a body part via a strap, such as a Velcro® strap.

According to one example, the hand-held machine comprises a hand-held tattoo machine. The tattoo machine is energized by a power source configured to be secured to the operator's arm, whereby the tattoo machine is electrically connected to the arm-fastened power source with a short power cable. The delivery of power to the tattoo machine alternates between on and off via operator commands activated remotely from a (RF) wireless foot pedal. When the arm-fastened power source receives a RF signal to turn on the delivery of power to the tattoo machine, the output of power is boosted and regulated by an adjustable voltage regulator.

For instance, the power source may provide an output voltage adjustable from approximately 4.5 volts to approximately 15 volts (V) DC (direct current), provide a maximum output current of about 2000 mA (milli-ampere), and provide a power efficiency of about 94%. A control dial on the arm-fastened power source may be accessed by the operator to adjust the output voltage. The power source may comprise a battery pack of fully charged Li-polymer batteries that can operate a standard tattoo machine continually for up to about 8 hours. For instance, the battery capacity may be about 4200 mAh (milli-ampere-hour), and the battery voltage may be about 3.7 V DC.

Additionally, for instance, the wireless foot pedal may be powered by one or more batteries, such as one or more lithium batteries. The battery capacity may be about 100 mAh, and the battery voltage may be about 12 V DC. A RF transmitter, operable at a transmission frequency of about 315 MHz (mega-Hertz), a transmission duration of about 250 msec (milliseconds), and an output power of about 5 mW, collaborates with a RF receiver in the arm-fastened power source. Under these conditions, the separation between the RF transmitter and RF receiver may be up to about 30 feet.

Optionally, a low battery warning is provided by a light emitting diode on the topside of the arm-fastened power source adjacent to the voltage control dial. For instance, the low battery warning can illuminate when the battery has 20% or less power remaining. Thereafter, the battery pack may be re-charged using a battery charger. For instance, the re-charging of the Li-polymer battery pack can require about 2 to 4 hours using a battery charger with an output current of about 1500 mAh, and an output voltage of about 4.2 V DC (for an input of 90 to 240 V AC). The elements, including the battery pack, the RF wireless receiver and the boost regulator circuit, as described above are commercially accessible and can be packaged within an enclosure wherein the entire device weighs less than approximately eight (8) ounces.

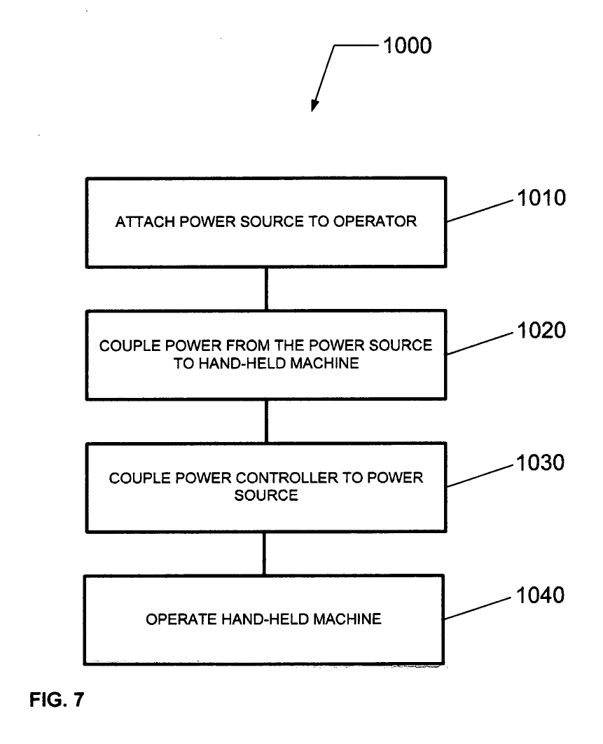

Referring now to FIG. 7, a method of operating a mobile power source with a hand-held machine is provided according to an embodiment. The method comprises a flow chart 1000 beginning in 1010 with fastening the mobile power source to an operator. For example, the mobile power source can be fastened to the operator using any of the attachment devices described above.

In 1020, power is coupled from the mobile power source to the hand-held machine by coupling an electrical power cable from an output of the hand-held machine to an input of the hand-held machine. For example, the hand-held machine can include a tattoo machine.

In 1030, a power controller is coupled to the mobile power source. For example, the power controller may be coupled to the mobile power source by disposing a foot pedal configured to control the output of power from the mobile power source on the floor in proximity to the mobile power source such that the foot pedal communicates with the mobile power source via a wireless connection.

In 1040, the hand-held machine is utilized by the operator, and the output of power from the mobile power source can be controlled via operation of the power controller. Additionally, upon completing the use of the hand-held machine, the mobile power source can be detached from the operator and the power supply may be detached from the attachment device. Furthermore, the power supply can be re-charged by plugging the power supply into an AC electrical outlet.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

What is claimed is:

1. A mobile power source for use with a hand-held machine, comprising:
a power supply configured to provide power to a hand-held machine, wherein said power supply excludes an electrical cord that tethers said power supply to an electrical outlet;
an attachment device coupled to said power supply and configured to fasten said power supply to an operator of said hand-held machine; and
a power cable configured to couple an output of said power supply to said hand-held machine.

2. The mobile power source of claim 1, wherein said hand-held machine comprises a tattoo machine.

3. The mobile power source of claim 1, further comprising:
a power controller coupled to said power supply and configured to turn on and turn off the output of power from said power supply to said hand-held machine.

4. The mobile power source of claim 3, wherein said power controller is coupled to said power supply via a wireless connection.

5. The mobile power source of claim 4, wherein said power controller comprises a foot pedal.

6. The mobile power source of claim 4, wherein said power controller comprises a radio frequency (RF) transmitter configured to transmit a RF signal and said power supply comprises a RF receiver configured to receive said signal transmitted from said RF transmitter, and wherein said RF signal is configured to designate a level of power to be output from said power supply.

7. The mobile power source of claim 1, wherein said power supply comprises one or more batteries, or one or more rechargeable batteries, or a combination thereof.

8. The mobile power source of claim 7, wherein said power supply can be detached from said operator and said one or more rechargeable batteries are recharged by coupling a battery charger from an electrical outlet to an input to said power supply.

9. The mobile power source of claim 1, further comprising:
a voltage controller coupled to said power supply and configured to regulate the electrical voltage output from said power supply.

10. The mobile power source of claim 1, wherein said attachment device comprises a strap configured to couple said power supply to an appendage of said operator.

11. The mobile power source of claim 10, wherein said strap comprises a Velcro® strap.

12. The mobile power source of claim 1, wherein said attachment device comprises a strap or dip or combination thereof configured to couple said power supply to the waist of said operator.

13. The mobile power source of claim 1, wherein said attachment device comprises a non-flexible, semi-flexible, or flexible attachment member configured to extend around or partially around the arm or forearm of said operator.

14. The mobile power source of claim 13, wherein said attachment member comprises one or more straps configured to secure said attachment member in place on the arm or forearm of said operator.

15. The mobile power source of claim 14, wherein said one or more straps comprise one or more Velcro® straps.

16. The mobile power source of claim 13, wherein said power supply is coupled to said attachment member via one or more straps.

17. The mobile power source of claim 13, wherein said attachment member comprises a pair of rails and said power supply is slidably coupled to said attachment member.

18. The mobile power source of claim 1, wherein said power supply is fixedly coupled to said attachment device or removably coupled to said attachment device.

19. A tattooing system, comprising:
a hand-held tattoo machine;
a mobile power supply configured to provide power to said hand-held tattoo machine;
an attachment device configured to fasten said mobile power supply to an operator of said hand-held tattoo machine;
a power cable configured to couple an output of said power supply to said hand-held machine; and
a foot pedal coupled to said power supply via a wireless connection and configured to turn on and turn off the output of power from said mobile power supply to said hand-held tattooing machine,
wherein the mobile power supply excludes an electrical cord that tethers the mobile power supply to an electrical outlet.

20. A method of providing power to a tattoo machine utilized by an operator, comprising:
attaching a power supply configured to provide power to said tattoo machine to the arm of said operator;
coupling an electrical power cord from an output of said tattoo machine to an input to said tattoo machine;
disposing a foot pedal configured to control the output of power from said power supply on the floor in proximity to said power supply such that said foot pedal communicates with said power supply via a wireless connection;
operating said tattoo machine; and
controlling the output of power from said power supply to said tattoo machine by operating said foot pedal.
